(19) United States
(12) Patent Application Publication
(10) Pub. No.: US 2026/0372093 A1
(43) Pub. Date: Nov. 19, 2026

(54) SEMICONDUCTOR DEVICE HAVING EFFECTIVE HEAT SPREADING, AND METHOD FOR MANUFACTURING THE SAME

(71) Applicant: TAIWAN SEMICONDUCTOR MANUFACTURING COMPANY, LTD., Hsinchu (TW)

(72) Inventors: Kun-Yen LIAO, Hsinchu (TW); Ming-Hsien LIN, Hsinchu (TW); Chia Chen LEE, Hsinchu (TW); Chia-Tien WU, Hsinchu (TW)

(73) Assignee: TAIWAN SEMICONDUCTOR MANUFACTURING COMPANY, LTD., Hsinchu (TW)

(21) Appl. No.: 19/212,200

(22) Filed: May 19, 2025

(51) Int. Cl. H10W 40/73; H10W 40/00

(52) U.S. Cl. CPC H10W 40/73; H10W 40/037

(57) ABSTRACT

A semiconductor device includes an interconnect structure and a plurality of heat pipes. The interconnect structure includes a plurality of first interconnect layers and a plurality of second interconnect layers. The first interconnect layers are formed in a dielectric layer, and each include a plurality of metal lines disposed in a device region of the semiconductor device. The second interconnect layers are formed in the dielectric layer, interleave the first interconnect layers, and each include a plurality of vias disposed in the device region. The heat pipes are formed in the dielectric layer, and are disposed outside the device region. A predetermined one of the second interconnect layers further includes a metal line that extends from a point in the device region to at least one of the heat pipes.

### BACKGROUND

A semiconductor device may have hot spots (areas of the semiconductor device that have temperatures apparently higher than an average temperature of the semiconductor device during operation). Hot spots may degrade maximum operation speed and reliability of the semiconductor device. Therefore, how to effectively spread heat generated at the hot spots away so as to decrease the temperatures of the hot spots is an important consideration.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating relative positions (in a Z direction) of various components of a semiconductor device in accordance with some embodiments.

FIG. 2 is a schematic diagram illustrating relative positions (in an X direction and a Y direction) of various components of a semiconductor device in accordance with some embodiments.

FIG. 3 is a schematic diagram illustrating relative positions (in an X direction and a Y direction) of various components of a semiconductor device in accordance with some embodiments.

FIG. 4 is a schematic diagram illustrating relative positions (in an X direction and a Y direction) of various components of a semiconductor device in accordance with some embodiments.

FIG. 5 is a schematic diagram illustrating relative positions (in an X direction and a Y direction) of various components of a semiconductor device in accordance with some embodiments.

FIGS. 6 and 7 are schematic sectional views of the semiconductor device respectively taken along lines A-A and B-B of FIG. 5 in accordance with some embodiments.

FIG. 8 is a schematic diagram illustrating relative positions (in an X direction and a Y direction) of various components of a semiconductor device in accordance with some embodiments.

FIG. 9 is a schematic sectional view of the semiconductor device taken along line C-C of FIG. 8 in accordance with some embodiments.

FIGS. 10 and 11 are flow charts illustrating a method for manufacturing a semiconductor device in accordance with some embodiments.

FIGS. 12 to 23 are schematic sectional views illustrating intermediate stages of a method for manufacturing a semiconductor device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

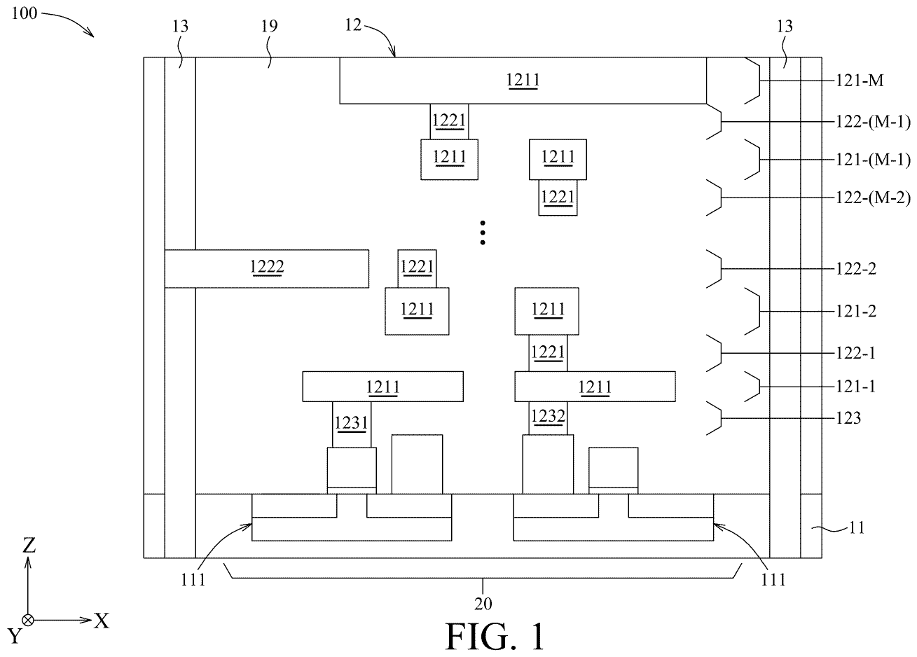

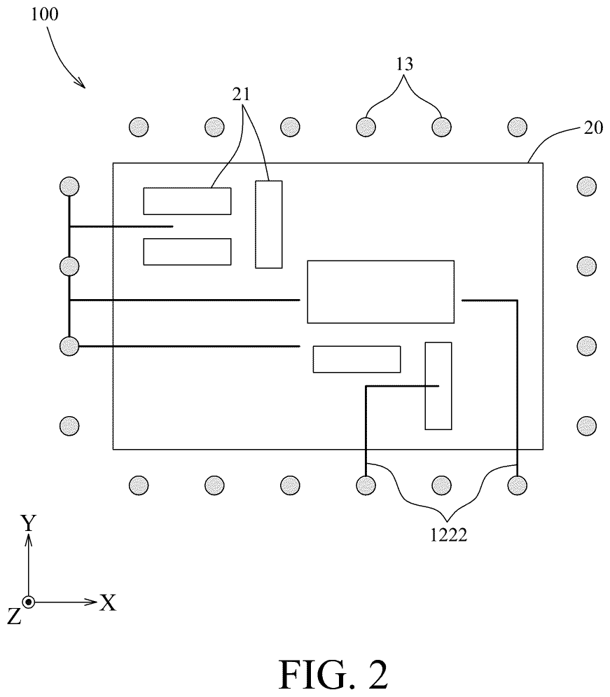

FIG. 1 is a schematic diagram illustrating relative positions (in a Z direction) of various components of a semiconductor device 100 in accordance with some embodiments. FIG. 2 is a schematic diagram illustrating relative positions (in an X direction and a Y direction) of various components of a semiconductor device 100 in accordance with some embodiments. Referring to FIGS. 1 and 2, the semiconductor device 100 has a device region 20, and includes a substrate 11, an interconnect structure 12 and a plurality of heat pipes 13. The substrate 11 includes a plurality of transistors 111 that are disposed in the device region 20. The interconnect structure 12 includes a plurality of first interconnect layers (121-1 to 121-M), a plurality of second interconnect layers (122-1 to 122-(M−1)) and a bottom interconnect layer 123. The first interconnect layers (121-1 to 121-M) (e.g., metal layers) are formed in a dielectric layer 19 disposed on the substrate 11, and each include a plurality of metal lines 1211 disposed in the device region 20. The second interconnect layers (122-1 to 122-(M−1)) (e.g., via layers) are formed in the dielectric layer 19, interleave the first interconnect layers (121-1 to 121-M), and each include a plurality of vias 1221 disposed in the device region 20. The bottom interconnect layer 123 (e.g., a via layer) is formed in the dielectric layer 19, is disposed below a bottommost one of the first interconnect layers 121-1, and includes a plurality of gate vias 1231 and a plurality of contact vias 1232 disposed in the device region 20. The transistors 111 are functionally connected by way of the metal lines 1211 of the first interconnect layers (121-1 to 121-M), the vias 1221 of the second interconnect layers (122-1 to 122-(M−1)), and the gate vias 1231 and the contact vias 1232 of the bottom interconnect layer 123 in a predetermined way, so the semiconductor device 100 can perform predetermined operations. The heat pipes 13 are formed in the substrate 11 and the dielectric layer 19, and are disposed outside the device region 20 and around at least one side of the device region 20. The heat pipes 13 are to be connected to a heat sink (not shown) disposed above or below the semiconductor device 100, and can facilitate spreading of heat generated by the semiconductor device 100 to the heat sink. A predetermined one of the second interconnect layers (122-m, where 1≤m≤(M−1)) further includes a plurality of metal lines 1222. Each of the metal lines 1222 extends from a point in the device region 20 to at least one of the heat pipes 13. The device region 20 has a plurality of hot spots 21. The hot spots 21 can be found in a design stage of the semiconductor device 100 by simulation using electronic design automation (EDA) tools. With respect to each of the metal lines 1222, the point from which the metal line 1222 extends may be within a selected one of the hot spots 21, at a boundary of the selected one of the hot spots 21, or outside and close to the selected one of the hot spots 21. The metal lines 1222 can facilitate spreading of heat generated by the semiconductor device 100 in the hot spots 21 to the heat pipes 13, thereby reducing temperatures of the hot spots 21 and enhancing a maximum operation speed and reliability of the semiconductor device 100.

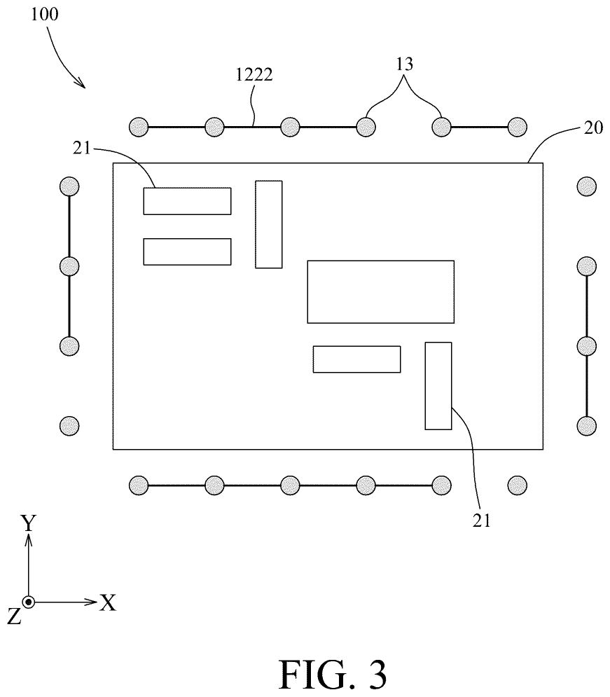

FIG. 3 is a schematic diagram illustrating relative positions (in the X direction and the Y direction) of various components of a semiconductor device 100 in accordance with some embodiments. Referring to FIG. 3, the semiconductor device 100 depicted in FIG. 3 is similar to the semiconductor device 100 depicted in FIG. 2, but differs from the semiconductor device 100 depicted in FIG. 2 in that: the metal lines 1222 are disposed outside the device region 20, and each are connected to at least two of the heat pipes 13. The metal lines 1222 can facilitate spreading of heat generated by the semiconductor device 100 among the heat pipes 13.

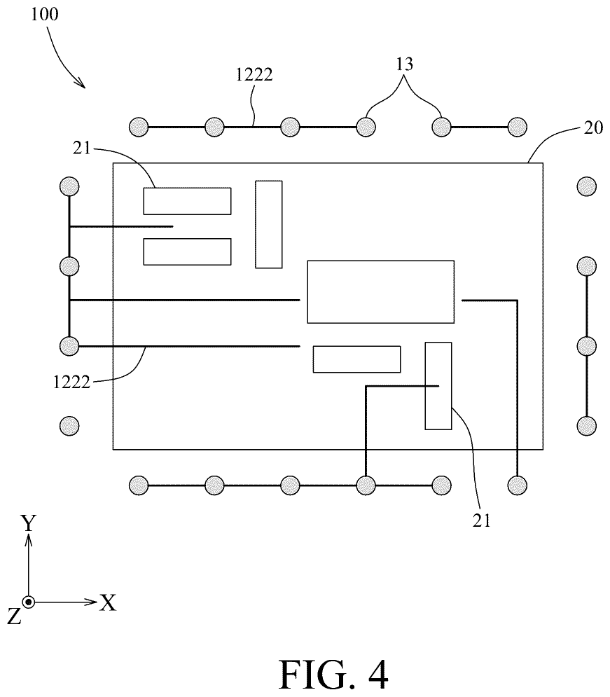

FIG. 4 is a schematic diagram illustrating relative positions (in the X direction and the Y direction) of various components of a semiconductor device 100 in accordance with some embodiments. Referring to FIG. 4, the semiconductor device 100 depicted in FIG. 4 is similar to the semiconductor device 100 depicted in FIG. 2, but differs from the semiconductor device 100 depicted in FIG. 2 in that: the metal lines 1222 are divided into a first group and a second group; the metal lines 1222 of the second group are disposed outside the device region 20, and each are connected to at least two of the heat pipes 13; and the metal lines 1222 of the first group each extend from a point in the device region 20 to one of the heat pipes 13 or one of the metal lines 1222 of the second group. With respect to each of the metal lines 1222 of the first group, the point from which the metal line 1222 extends may be within a selected one of the hot spots 21, at a boundary of the selected one of the hot spots 21, or outside and close to the selected one of the hot spots 21. The metal lines 1222 can not only facilitate spreading of heat generated by the semiconductor device 100 in the hot spots 21 to the heat pipes 13, but can also facilitate spreading of heat generated by the semiconductor device 100 among the heat pipes 13.

Referring back to FIGS. 1 and 2, in some embodiments, the vias 1221 and the metal lines 1222 of the predetermined one of the second interconnect layers (122-m) may be made of copper (Cu), cobalt (Co), tungsten (W), molybdenum (Mo), ruthenium (Ru), aluminum (Al), niobium (Nb), copper aluminum (CuₓAlₓ), nickel aluminum (NiₓAlₓ), other suitable materials, or combinations thereof.

In some embodiments, the heat pipes 13 may be made of copper (Cu), aluminum (Al), tungsten (W), molybdenum (Mo), aluminum nitride (AlN), other suitable materials, or combinations thereof.

In some embodiments, each of the metal lines 1222 may have a minimum width that is no less than about 10 nm. When the minimum width is less than about 10 nm, it may be difficult to manufacture the metal line 1222.

In some embodiments, the predetermined one of the second interconnect layers (122-m) may have a via density that falls within a range of from about 0.5% to about 20%. When the via density is less than about 0.5%, it may be difficult to interconnect the metal lines 121 of the first interconnect layer (121-m) and the metal lines 1211 of the first interconnect layer (121-(m+1)). When the via density is greater than about 20%, it may be difficult to route the metal lines 1222.

In some embodiments, the predetermined one of the second interconnect layers (122-m) may have a thickness that falls within a range of from about 100 Å to about 500 Å. When the thickness is less than about 100 Å, heat spreading effect of the metal lines 1222 may be poor. When the thickness is greater than about 500 Å, it may be difficult to manufacture the vias 1221 and the metal lines 1222 of the predetermined one of the second interconnect layers (122-m), and resistances of the vias 1221 of the predetermined one of the second interconnect layers (122-m) may be large.

In some embodiments, each of the two first interconnect layers (121-m, 121-(m+1)) that are adjacent to the predetermined one of the second interconnect layers (122-m) may have a minimum pitch that is no greater than about 100 nm when 1≤m≤2. When the minimum pitch is greater than about 100 nm, the semiconductor device 100 may occupy a large area.

In some embodiments, each of the two first interconnect layers (121-m, 121-(m+1)) that are adjacent to the predetermined one of the second interconnect layers (122-m) may have a thickness that falls within a range of from about 100 Å to about 1000 Å when 1≤m≤2. When the thickness is less than about 100 Å, resistances of the metal lines 1211 of the first interconnect layer (121-m or 121-(m+1)) may be large. When the thickness is greater than about 1000 Å, it may be difficult to manufacture the metal lines 1211 of the first interconnect layer (121-m or 121-(m+1)).

In some embodiments, each of the heat pipes 13 may have a cylinder shape, and may have a radius that falls within a range of from about 20 nm to about 1000 nm. When the radius is less than about 20 nm, it may be difficult to manufacture the heat pipe 13. When the radius is greater than about 1000 nm, the semiconductor device 100 may occupy a large area.

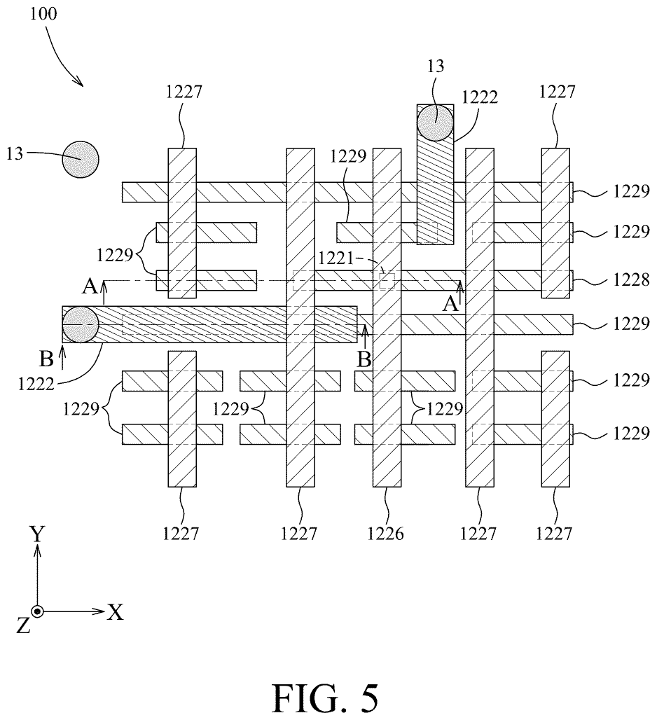

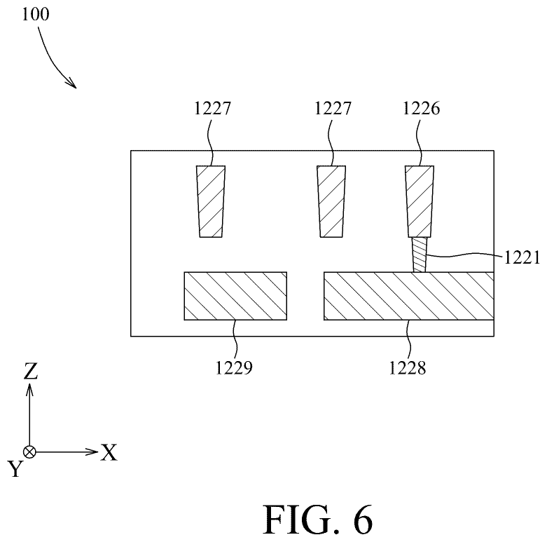

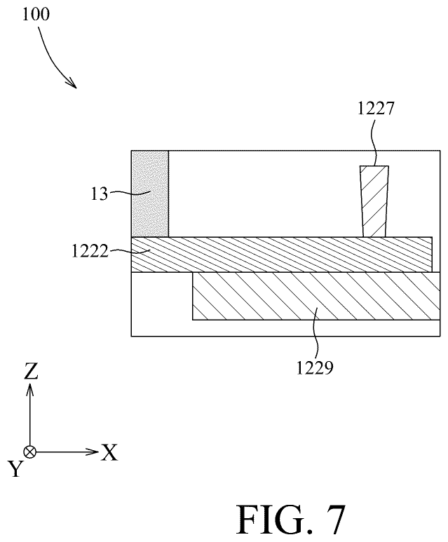

FIG. 5 is a schematic diagram illustrating relative positions (in the X direction and the Y direction) of various components of a semiconductor device 100 in accordance with some embodiments. FIGS. 6 and 7 are schematic sectional views of the semiconductor device 100 respectively taken along lines A-A and B-B of FIG. 5 in accordance with some embodiments. Referring to FIGS. 1, 2 and 5 to 7, FIG. 5 illustrates an exemplary layout of the predetermined one of the second interconnect layers (122-m), the two first interconnect layers (121-m, 121-(m+1)) and the heat pipes 13 of the semiconductor device 100 depicted in FIGS. 1 and 2. As shown in FIG. 5, some of the metal lines 1222 may extend in a first direction (e.g., the X direction), and the other ones of the metal lines 1222 may extend in a second direction (e.g., the Y direction). Some of the metal lines 1221 of the first interconnect layer (121-(m+1)) serve as signal lines 1226 for transmitting signals, and the other ones of the metal lines 1221 of the first interconnect layer (121-(m+1)) serve as dummy lines 1227 to control widths and spacings of the signal lines 1226 during fabrication of the semiconductor device 100. Some of the metal lines 1221 of the first interconnect layer (121-m) serve as signal lines 1228 for transmitting signals, and the other ones of the metal lines 1221 of the first interconnect layer (121-m) serve as dummy lines 1229 to control widths and spacings of the signal lines 1228 during fabrication of the semiconductor device 100.

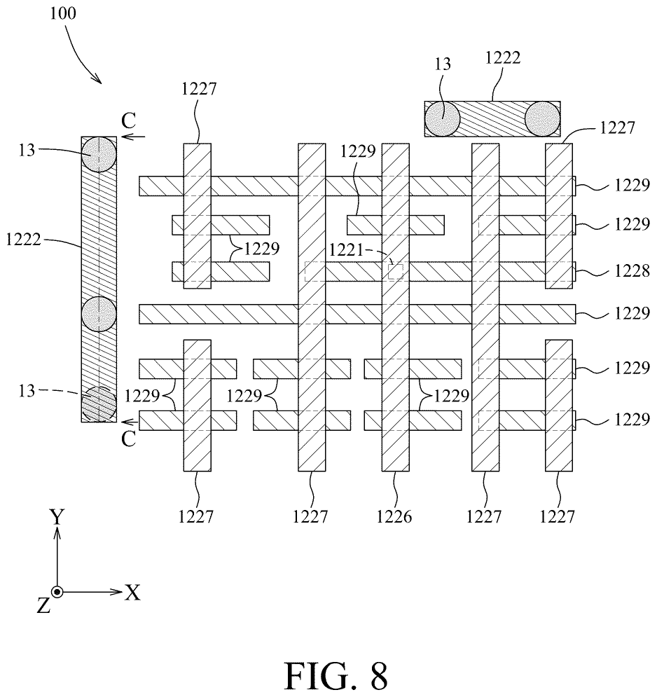

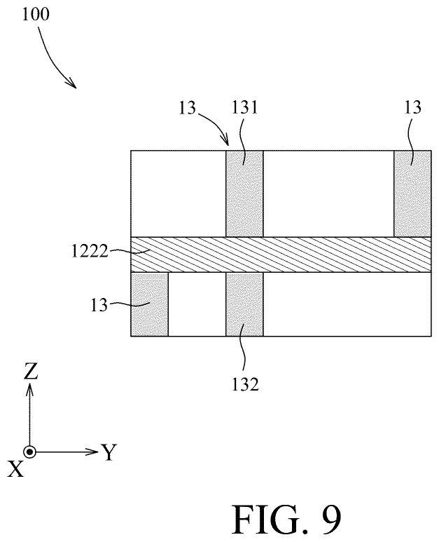

FIG. 8 is a schematic diagram illustrating relative positions (in the X direction and the Y direction) of various components of a semiconductor device 100 in accordance with some embodiments. FIG. 9 is a schematic sectional view of the semiconductor device 100 taken along line C-C of FIG. 8 in accordance with some embodiments. Referring to FIGS. 1, 3, 8 and 9, FIG. 8 illustrates an exemplary layout of the predetermined one of the second interconnect layers (122-m), the two first interconnect layers (121-m, 121-(m+1)) and the heat pipes 13 of the semiconductor device 100 depicted in FIGS. 1 and 3. As shown in FIG. 8, some of the metal lines 1222 may extend in the X direction, and the other ones of the metal lines 1222 may extend in the Y direction. Some of the metal lines 1221 of the first interconnect layer (121-(m+1)) serve as signal lines 1226 for transmitting signals, and the other ones of the metal lines 1221 of the first interconnect layer (121-(m+1)) serve as dummy lines 1227 to control widths and spacings of the signal lines 1226 during fabrication of the semiconductor device 100. Some of the metal lines 1221 of the first interconnect layer (121-m) serve as signal lines 1228 for transmitting signals, and the other ones of the metal lines 1221 of the first interconnect layer (121-m) serve as dummy lines 1229 to control widths and spacings of the signal lines 1228 during fabrication of the semiconductor device 100. As shown in FIG. 9, some of the heat pipes 13 may be wholly formed above the metal lines 1222. Some other ones of the heat pipes 13 may be wholly formed below the metal lines 1222. Still other ones of the heat pipes 13 may each have a first heat pipe portion 131 that is formed above the metal lines 1222, and a second heat pipe portion 132 that is formed below the metal lines 1222 and that is aligned with the first heat pipe portion 131.

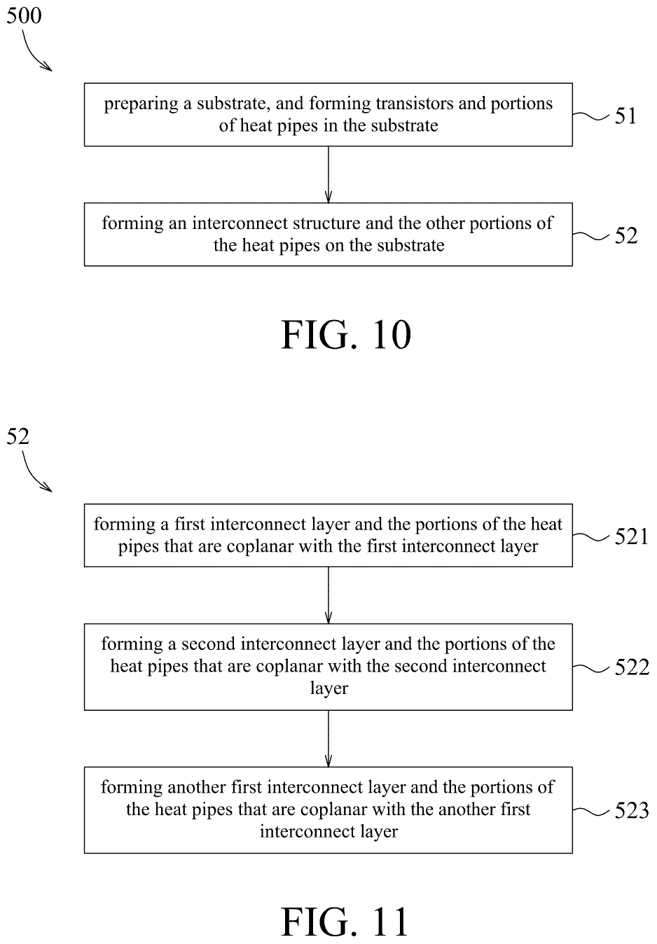

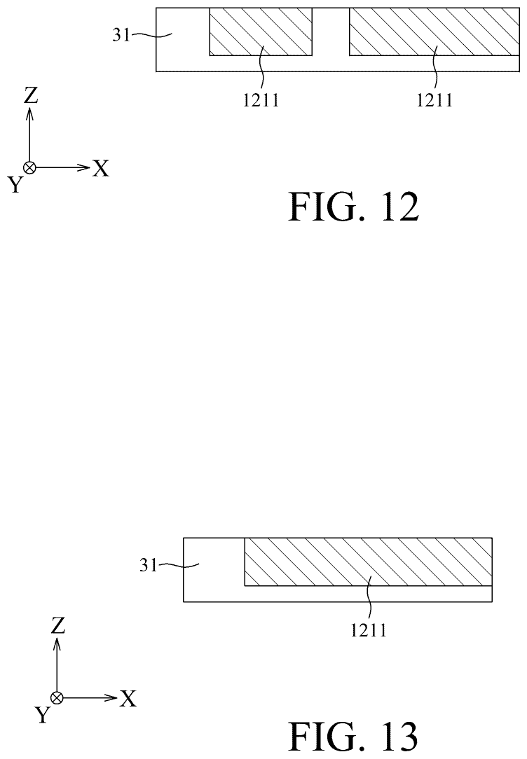

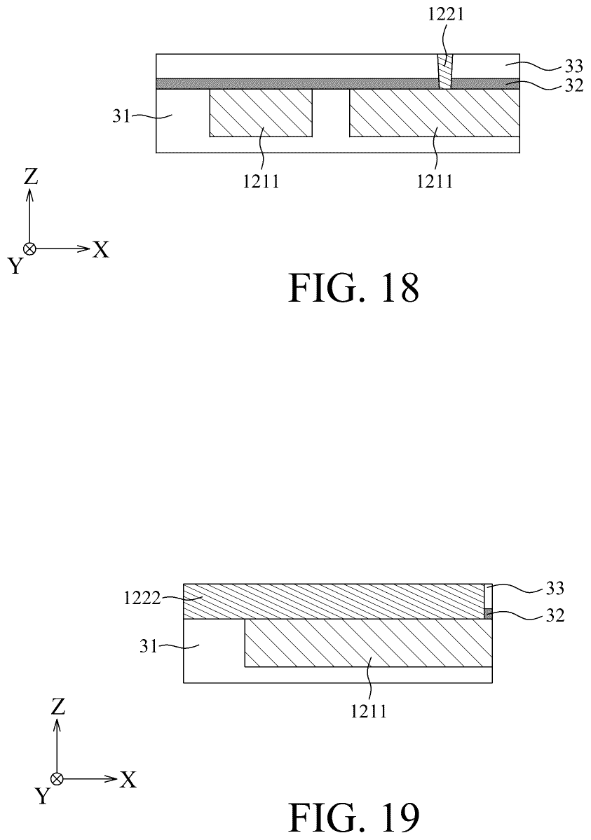

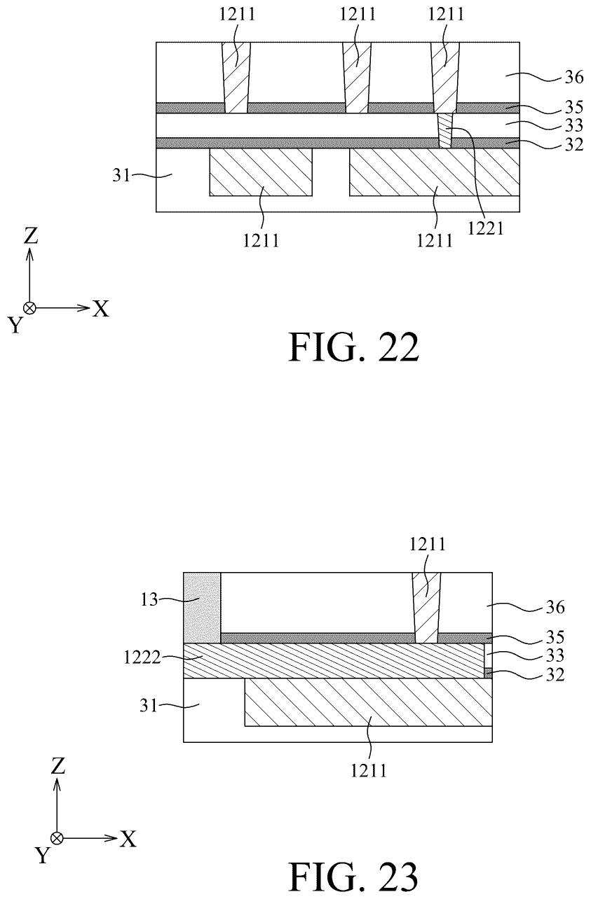

FIGS. 10 and 11 are flow charts illustrating a method 500 for manufacturing a semiconductor device in accordance with some embodiments. FIGS. 12 to 23 are schematic sectional views of semiconductor structures during various stages of the method 500. The method 500 and the semiconductor structures will be described together below. It should be noted that additional steps can be provided before, during or after the method 500, and some of the steps described herein may be replaced by other steps or be eliminated. Similarly, further additional features may be present in the semiconductor structures, and/or features present may be replaced or eliminated in additional embodiments.

Referring to FIGS. 1, 2 and 10, the method 500 begins at step 51, where the substrate 11 is prepared, and then the transistors 111 and portions of the heat pipes 13 are formed in the substrate 11. In some embodiments, the substrate 11 may be made of elemental semiconductor materials (e.g., crystalline silicon (Si), diamond, germanium (Ge) or the like), compound semiconductor materials (e.g., gallium nitride (GaN), silicon carbide (SiC), gallium arsenide (GaAs), indium arsenide (InAs), indium phosphide (InP) or the like), or alloy semiconductor materials (e.g., silicon germanium (SiGe), silicon germanium carbide, gallium arsenic phosphide (GaAsP), gallium indium phosphide (GaInP) or the like). The material for forming the substrate 11 may be doped with p-type impurities (e.g., boron (B), aluminum (Al), gallium (Ga) or the like) or n-type impurities (e.g., phosphorous (P), antimony (Sb), arsenic (As) or the like), or undoped. In addition, the substrate 11 may be a bulk silicon substrate, a silicon-on-insulator (SOI) substrate, or a germanium-on-insulator (GOI) substrate. Other suitable materials and/or configurations for the substrate 11 are within the contemplated scope of the present disclosure. In some embodiments, the transistors 111 may be planar field effect transistors (planar FETs), three-dimensional field effect transistors (3D FETs) such as fin field effect transistors (FinFETs), or the like, and may be formed in the substrate 11 by a suitable process known in the art of semiconductor fabrication.

The method 500 then proceeds to step 52, where the interconnect structure 12 and the other portions of the heat pipes 13 are formed on the substrate 11. In some embodiments, the bottom interconnect layer 123, the first interconnect layer 121-1, the second interconnect layer 122-1, the first interconnect layer 121-2, the second interconnect layer 122-2, . . . , the second interconnect layer (122-(M−2)), the first interconnect layer (121-(M−1)), the second interconnect layer (122-(M−1)) and the first interconnect layer 121-M may be formed sequentially in the given order. In some embodiments, with respect to each of the first interconnect layers (121-1 to 121-M), the second interconnect layers (122-1 to 122-(M−1)) and the bottom interconnect layer 123, portions of the heat pipes 13 that are coplanar with the interconnect layer may be formed with the interconnect layer simultaneously.

In some embodiments, the metal lines 1211 of the first interconnect layers (121-1 to 121-M), the metal lines 1222 of the predetermined one of the second interconnect layers (122-m), the vias 1221 of the second interconnect layers (122-1 to 122-(M−1)), and the gate vias 1231 and the contact vias 1232 of the bottom interconnect layer 123 may be made of copper (Cu), cobalt (Co), tungsten (W), molybdenum (Mo), ruthenium (Ru), aluminum (Al), niobium (Nb), copper aluminum (CuₓAlₓ), nickel aluminum (NiₓAlₓ), other suitable materials, or combinations thereof.

In some embodiments, the heat pipes 13 may be made of copper (Cu), aluminum (Al), tungsten (W), molybdenum (Mo), aluminum nitride (AlN), other suitable materials, or combinations thereof.

FIGS. 12 to 23 illustrate an example where a layout of the predetermined one of the second interconnect layers (122-m), the two first interconnect layers (121-m, 121-(m+1)) and the heat pipes 13 of the semiconductor device 100 is as depicted in FIG. 5, where FIGS. 12, 14, 16, 18, 20 and 22 are schematic sectional views similar to FIG. 6, and FIGS. 13, 15, 17, 19, 21 and 23 are schematic sectional views similar to FIG. 7. The predetermined one of the second interconnect layers (122-m), the two first interconnect layers (121-m, 121-(m+1)), and the portions of the heat pipes 13 that are coplanar with any one of the interconnect layers (121-m, 121-(m+1), 122-m,) may be formed the way shown in FIG. 11.

Referring to FIGS. 1, 5 and 11 to 13, in sub-step 521, the first interconnect layer (121-m) and the portions of the heat pipes 13 that are coplanar with the first interconnect layer (121-m) are formed. In some embodiments, the first interconnect layer (121-m) and the portions of the heat pipes 13 may be formed by: (a) depositing a dielectric material 31; (b) patterning the dielectric material 31 to form a plurality of first recesses for accommodating the metal lines 1211 of the first interconnect layer (121-m) and a plurality of second recesses for accommodating the portions of the heat pipes 13; (c) depositing a conductive material for forming the metal lines 1211 of the first interconnect layer (121-m) and the portions of the heat pipes 13 on the dielectric material, so as to fill the first recesses and the second recesses; and (d) removing superfluous conductive material to expose the dielectric material 31. The remaining portion of the dielectric material 31 serves as a portion of the dielectric layer 19. The remaining portions of the conductive material in the first recesses are referred to as the metal lines 1211 of the first interconnect layer (121-m). The remaining portions of the conductive material in the second recesses are referred to as the portions of the heat pipes 13. In some embodiments, the dielectric material 31 may be deposited using, for example, chemical vapor deposition (CVD), physical vapor deposition (PVD), other suitable techniques, or combinations thereof. In some embodiments, the dielectric material 31 may be made of, for example, silicon oxide, silicon nitride, silicon carbide, silicon oxycarbide, silicon oxynitride, silicon carbonitride, silicon oxycarbonitride, undoped silicate glass (USG), phosphosilicate glass (PSG), borosilicate glass (BSG), boron-doped phosphosilicate glass (BPSG), fluorine-doped silicate glass (FSG), porous carbon-doped silicon oxide, other suitable materials, or combinations thereof. In some other embodiments, the dielectric material 31 may be made of, for example, polyimide, epoxy resin, acrylic resin, phenol resin, benzocyclobutene (BCB), polybenzooxazole (PBO), other suitable polymer-based materials, or combinations thereof. In some embodiments, the dielectric material 31 may be patterned using a photolithography process and an etching process. The photolithography process may include, for example, but not limited to, coating a photoresist, soft-baking, exposing the photoresist through a photomask, post-exposure baking, and developing the photoresist, followed by hard-baking so as to form a patterned photoresist. The etching process may be implemented by etching the dielectric material 31 through the patterned photoresist using, for example, dry etching, wet etching, other suitable techniques, or combinations thereof. The patterned photoresist may be removed after the etching process. In some embodiments, the conductive material may be deposited using, for example, chemical vapor deposition (CVD), physical vapor deposition (PVD), electroless plating, electroplating, other suitable techniques, or combinations thereof. In some embodiments, the superfluous conductive material may be removed using, for example, chemical mechanical polishing (CMP), or other suitable planarization techniques.

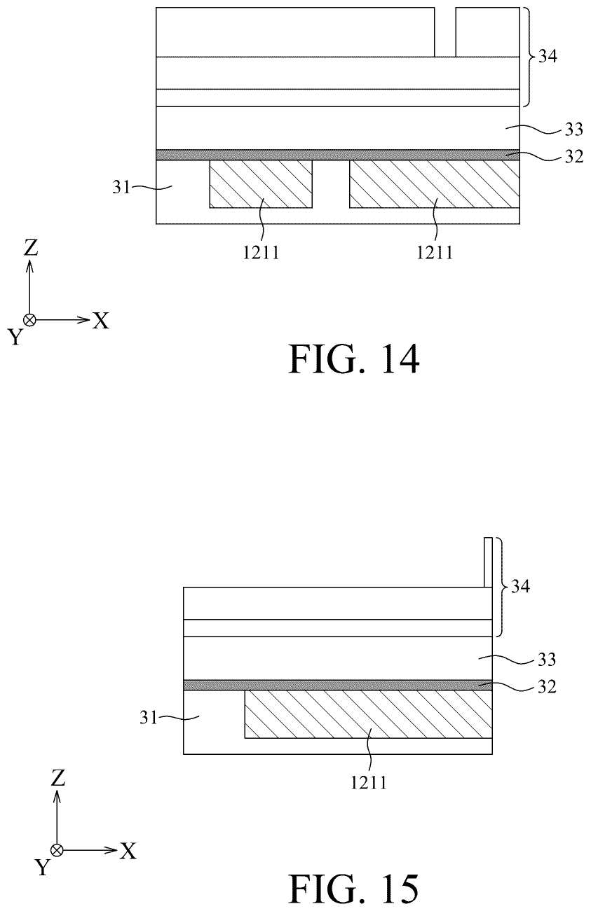

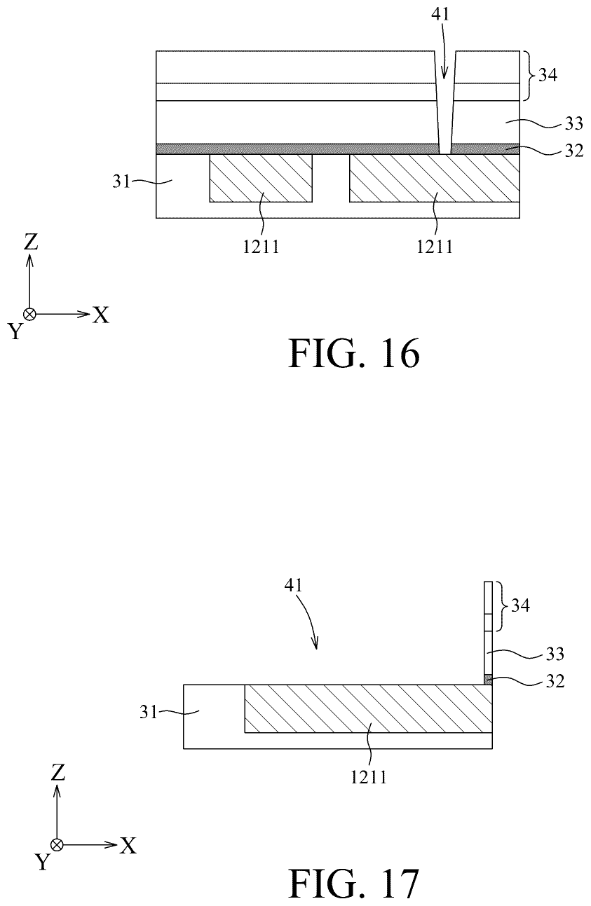

Referring to FIGS. 1, 5, 11 and 14 to 19, in sub-step 522, the second interconnect layer (122-m) and the portions of the heat pipes 13 that are coplanar with the second interconnect layer (122-m) are formed. In some embodiments, the second interconnect layer (122-m) and the portions of the heat pipes 13 may be formed as described below. First, as shown in FIGS. 14 and 15, an etch stop layer 32 is deposited using, for example, chemical vapor deposition (CVD), physical vapor deposition (PVD), atomic layer deposition (ALD), other suitable techniques, or combinations thereof. In some embodiments, the etch stop layer 32 may be made of aluminum compounds (e.g., aluminum nitride, aluminum oxynitride, aluminum oxide, etc.), silicon compounds (e.g., silicon oxycarbide, silicon carbonitride, silicon nitride, silicon oxycarbonitride, etc.), other suitable materials, or combinations thereof. Next, as shown in FIGS. 14 to 15, a dielectric material 33 is deposited on the etch stop layer 34 using, for example, chemical vapor deposition (CVD), physical vapor deposition (PVD), other suitable techniques, or combinations thereof. In some embodiments, the dielectric material 33 may be made of, for example, silicon oxide, silicon nitride, silicon carbide, silicon oxycarbide, silicon oxynitride, silicon carbonitride, silicon oxycarbonitride, undoped silicate glass (USG), phosphosilicate glass (PSG), borosilicate glass (BSG), boron-doped phosphosilicate glass (BPSG), fluorine-doped silicate glass (FSG), porous carbon-doped silicon oxide, other suitable materials, or combinations thereof. In some other embodiments, the dielectric material 33 may be made of, for example, polyimide, epoxy resin, acrylic resin, phenol resin, benzocyclobutene (BCB), polybenzoxazole (PBO), other suitable polymer-based materials, or combinations thereof. Then, as shown in FIGS. 14 and 15, a mask layer 34 is deposited on the dielectric material 33 using, for example, physical vapor deposition (PVD), chemical vapor deposition (CVD), atomic layer deposition (ALD), other suitable techniques, or combinations thereof. In some embodiments, the mask layer 34 may have multiple sub-layers (e.g., three sub-layers), and each of the sub-layers may be made of, for example, silicon oxide, silicon nitride, silicon carbide, silicon oxycarbide, silicon oxynitride, silicon carbonitride, silicon oxycarbonitride, cobalt, ruthenium, tungsten, titanium nitride, zirconium oxide, aluminum oxide, yttrium oxide, aluminum oxynitride, hafnium oxide, hafnium zirconium oxide, hafnium silicon oxide, hafnium silicon oxynitride, zirconium silicon oxide, hafnium zirconium silicon oxide, hafnium aluminum oxide, hafnium aluminum nitride, zirconium aluminum oxide, ytterbium oxide, other suitable materials, or combinations thereof. Next, as shown in FIGS. 14 to 17, the mask layer 34, the dielectric material 33 and the etch stop layer 32 are patterned so as to form a plurality of first recesses 41 for accommodating the vias 1221 and the metal lines 1222 of the second interconnect layer (122-m) and a plurality of second recesses for accommodating the portions of the heat pipes 13. In some embodiments, the mask layer 34 may be patterned using photolithography and photoresist developing technology as is known to those skilled in the art of semiconductor fabrication. A pattern formed in the mask layer 34 is then transferred to the dielectric material 33 and the etch stop layer 32 by one or more etching processes, so as to form the first recesses 41 and the second recesses. At least one of the sub-layers (e.g., the topmost sub-layer) of the mask layer 34 may be removed during the one or more etching processes. Then, as shown in FIGS. 16 to 19, a conductive material for forming the vias 1221 and the metal lines 1222 of the second interconnect layer (122-m) and the portions of the heat pipes 13 is deposited on the mask layer 34 using, for example, chemical vapor deposition (CVD), physical vapor deposition (PVD), electroless plating, electroplating, other suitable techniques, or combinations thereof, so as to fill the first recesses 41 and the second recesses. Lastly, as shown in FIGS. 16 to 19, the mask layer 34 and superfluous conductive material are removed using, for example, chemical mechanical polishing (CMP), or other suitable planarization techniques, so as to expose the dielectric material 33. The remaining portion of the dielectric material 33 serves as a portion of the dielectric layer 19. The remaining portions of the conductive material in the first recesses 41 are referred to as the vias 1221 and the metal lines 1222 of the second interconnect layer (122-m). The remaining portions of the conductive material in the second recesses are referred to as the portions of the heat pipes 13.

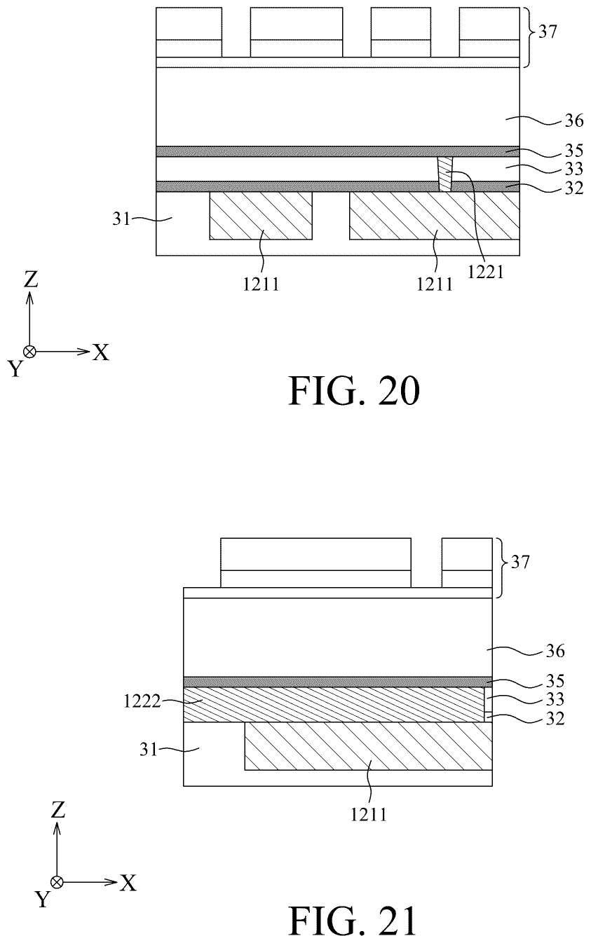

Referring to FIGS. 1, 5, 11 and 20 to 23, in sub-step 523, the first interconnect layer (121-(m+1)) and the portions of the heat pipes 13 that are coplanar with the first interconnect layer (121-(m+1)) are formed. In some embodiments, the first interconnect layer (121-(m+1)) and the portions of the heat pipes 13 may be formed as described below. First, as shown in FIGS. 20 and 21, an etch stop layer 35 is deposited using, for example, chemical vapor deposition (CVD), physical vapor deposition (PVD), atomic layer deposition (ALD), other suitable techniques, or combinations thereof. In some embodiments, the etch stop layer 35 may be made of aluminum compounds (e.g., aluminum nitride, aluminum oxynitride, aluminum oxide, etc.), silicon compounds (e.g., silicon oxycarbide, silicon carbonitride, silicon nitride, silicon oxycarbonitride, etc.), other suitable materials, or combinations thereof. Next, as shown in FIGS. 20 and 21, a dielectric material 36 is deposited on the etch stop layer 35 using, for example, chemical vapor deposition (CVD), physical vapor deposition (PVD), other suitable techniques, or combinations thereof. In some embodiments, the dielectric material 36 may be made of, for example, silicon oxide, silicon nitride, silicon carbide, silicon oxycarbide, silicon oxynitride, silicon carbonitride, silicon oxycarbonitride, undoped silicate glass (USG), phosphosilicate glass (PSG), borosilicate glass (BSG), boron-doped phosphosilicate glass (BPSG), fluorine-doped silicate glass (FSG), porous carbon-doped silicon oxide, other suitable materials, or combinations thereof. In some other embodiments, the dielectric material 36 may be made of, for example, polyimide, epoxy resin, acrylic resin, phenol resin, benzocyclobutene (BCB), polybenzoxazole (PBO), other suitable polymer-based materials, or combinations thereof. Then, as shown in FIGS. 20 and 21, a mask layer 37 is deposited on the dielectric material 36 using, for example, physical vapor deposition (PVD), chemical vapor deposition (CVD), atomic layer deposition (ALD), other suitable techniques, or combinations thereof. In some embodiments, the mask layer 37 may have multiple sub-layers (e.g., three sub-layers), and each of the sub-layers may be made of, for example, silicon oxide, silicon nitride, silicon carbide, silicon oxycarbide, silicon oxynitride, silicon carbonitride, silicon oxycarbonitride, cobalt, ruthenium, tungsten, titanium nitride, zirconium oxide, aluminum oxide, yttrium oxide, aluminum oxynitride, hafnium oxide, hafnium zirconium oxide, hafnium silicon oxide, hafnium silicon oxynitride, zirconium silicon oxide, hafnium zirconium silicon oxide, hafnium aluminum oxide, hafnium aluminum nitride, zirconium aluminum oxide, ytterbium oxide, other suitable materials, or combinations thereof. Next, as shown in FIGS. 20 to 23, the mask layer 37, the dielectric material 36 and the etch stop layer 35 are patterned so as to form a plurality of first recesses for accommodating the metal lines 1211 of the first interconnect layer (121-(m+1)) and a plurality of second recesses for accommodating the portions of the heat pipes 13. In some embodiments, the mask layer 37 may be patterned using photolithography and photoresist developing technology as is known to those skilled in the art of semiconductor fabrication. A pattern formed in the mask layer 37 is then transferred to the dielectric material 36 and the etch stop layer 35 by one or more etching processes, so as to form the first recesses and the second recesses. Then, as shown in FIGS. 20 to 23, a conductive material for forming the metal lines 1211 of the first interconnect layer (121-(m+1)) and the portions of the heat pipes 13 is deposited on the mask layer 37 using, for example, chemical vapor deposition (CVD), physical vapor deposition (PVD), electroless plating, electroplating, other suitable techniques, or combinations thereof, so as to fill the first recesses and the second recesses. Lastly, the mask layer 37 and superfluous conductive material are removed using, for example, chemical mechanical polishing (CMP), or other suitable planarization techniques, so as to expose the dielectric material 36. The remaining portion of the dielectric material 36 serves as a portion of the dielectric layer 19. The remaining portions of the conductive material in the first recesses are referred to as the metal lines 1211 of the first interconnect layer (121-(m+1)). The remaining portions of the conductive material in the second recesses are referred to as the portions of the heat pipes 13.

It should be noted that, with respect to each of the substrate 11, the bottom interconnect layer 123, the first interconnect layers (121-1 to 121-M, except 121-m and 121-(m+1)) and the second interconnect layers (122-1 to 122-(M−1), except 122-m), the corresponding portions of the heat pipes 13 may be formed in a way similar to the portions of the heat pipes 13 that correspond to any one of the first interconnect layers (121-m, 121-(m+1)) and the second interconnect layer (122-m). Moreover, with respect to each of the first interconnect layers (121-1 to 121-M, except 121-m and 121-(m+1)), the metal lines 1211 of the first interconnect layer may be formed in a way similar to the metal lines 1211 of any one of the first interconnect layers (121-m, 121-(m+1)). Furthermore, with respect to each of the second interconnect layers (122-1 to 122-(M−1), except 122-m), the vias 1221 of the second interconnect layer may be formed in a way similar to the vias 1221 of the second interconnect layer (122-m). In addition, the gate vias 1231 and the contact vias 1232 of the bottom interconnect layer 123 may be formed in a way similar to the vias 1221 of the second interconnect layer (122-m).

In view of the above, since the second interconnect layer (122-m) and the first interconnect layer (121-(m+1)) are formed separately, and since the second interconnect layer (122-m) has a low via density, routing of the metal lines 1222 can be very flexible. Each of the metal line 1222 can have a one-dimensional layout or a two-dimensional layout. In addition, since the metal lines 1222 are formed simultaneously with the vias 1221 of the second interconnect layer (122-m), no extra mask layer is needed during fabrication of the semiconductor device 100.

In accordance with some embodiments of the present disclosure, a semiconductor device has a device region, and includes an interconnect structure and a plurality of heat pipes. The interconnect structure includes a plurality of first interconnect layers and a plurality of second interconnect layers. The plurality of first interconnect layers are formed in a dielectric layer, and each include a plurality of metal lines disposed in the device region. The plurality of second interconnect layers are formed in the dielectric layer, interleave the plurality of the first interconnect layers, and each include a plurality of vias disposed in the device region. The plurality of heat pipes are formed in the dielectric layer, and are disposed outside the device region. A predetermined one of the plurality of second interconnect layers further includes a first metal line that extends from a point in the device region to at least one of the plurality of heat pipes.

In accordance with some embodiments of the present disclosure, the predetermined one of the plurality of second interconnect layers further includes a second metal line that is disposed outside the device region and that is connected to at least two of the plurality of heat pipes.

In accordance with some embodiments of the present disclosure, the device region includes a hot spot. The point from which the first metal line extends is within the hot spot.

In accordance with some embodiments of the present disclosure, the device region includes a hot spot. The point from which the first metal line extends is at a boundary of the hot spot.

In accordance with some embodiments of the present disclosure, the device region includes a hot spot. The point from which the first metal line extends is outside of the hot spot and close to the hot spot.

In accordance with some embodiments of the present disclosure, the first metal line has a minimum width that is no less than 10 nm.

In accordance with some embodiments of the present disclosure, the predetermined one of the plurality of second interconnect layers has a via density that falls within a range of from 0.5% to 20%.

In accordance with some embodiments of the present disclosure, a pair of the plurality of first interconnect layers that is adjacent to the predetermined one of the plurality of second interconnect layers has a minimum pitch that is no greater than 100 nm.

In accordance with some embodiments of the present disclosure, a pair of the plurality of first interconnect layers that is adjacent to the predetermined one of the plurality of second interconnect layers has a thickness that falls within a range of from 100 Å to 1000 Å.

In accordance with some embodiments of the present disclosure, the predetermined one of the plurality of second interconnect layers has a thickness that falls within a range of from 100 Å to 500 Å.

In accordance with some embodiments of the present disclosure, each of the plurality of heat pipes has a radius that falls within a range of from 20 nm to 1000 nm.

In accordance with some embodiments of the present disclosure, a semiconductor device has a device region, and includes an interconnect structure and a plurality of heat pipes. The interconnect structure includes a plurality of first interconnect layers and a plurality of second interconnect layers. The plurality of first interconnect layers are formed in a dielectric layer, and each include a plurality of metal lines disposed in the device region. The plurality of second interconnect layers are formed in the dielectric layer, interleave the plurality of the first interconnect layers, and each include a plurality of vias disposed in the device region. The plurality of heat pipes are formed in the dielectric layer, and are disposed outside the device region. A predetermined one of the plurality of second interconnect layers further includes a first metal line that is disposed outside the device region and that is connected to at least two of the plurality of heat pipes.

In accordance with some embodiments of the present disclosure, the predetermined one of the plurality of second interconnect layers further includes a second metal line that extends from a point in the device region to the first metal line.

In accordance with some embodiments of the present disclosure, the device region includes a hot spot. The point from which the second metal line extends is within the hot spot.

In accordance with some embodiments of the present disclosure, the device region includes a hot spot. The point from which the second metal line extends is at a boundary of the hot spot.

In accordance with some embodiments of the present disclosure, the device region includes a hot spot. The point from which the second metal line extends is outside of the hot spot and close to the hot spot.

In accordance with some embodiments of the present disclosure, a method for manufacturing a semiconductor device includes: forming a first interconnect layer and a plurality of first heat pipe portions, where the first interconnect layer includes a plurality of metal lines that are disposed in a device region of the semiconductor device, and the plurality of first heat pipe portions are disposed outside the device region; forming a second interconnect layer that includes a plurality of vias and a first metal line, where the plurality of vias are disposed in the device region, and the first metal line extends from a point in the device region to outside of the device region; and forming a third interconnect layer and a plurality of second heat pipe portions, where the third first interconnect layer includes a plurality of metal lines that are disposed in the device region, and the plurality of second heat pipe portions are disposed outside the device region. The first metal line is connected to at least one of the plurality of first heat pipe portions and the plurality of second heat pipe portions.

In accordance with some embodiments of the present disclosure, the second interconnect layer further includes a second metal line that is disposed outside the device region and that is connected to at least two of the plurality of first heat pipe portions.

In accordance with some embodiments of the present disclosure, the second interconnect layer further includes a second metal line that is disposed outside the device region and that is connected to at least two of the plurality of second heat pipe portions.

In accordance with some embodiments of the present disclosure, the plurality of vias and the first metal line are made of copper, cobalt, tungsten, molybdenum, ruthenium, aluminum, niobium, copper aluminum, nickel aluminum, or combinations thereof.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device including a device region, and comprising:
an interconnect structure including
a plurality of first interconnect layers formed in a dielectric layer, and each including a plurality of metal lines disposed in the device region, and
a plurality of second interconnect layers formed in the dielectric layer, interleaving the plurality of the first interconnect layers, and each including a plurality of vias disposed in the device region; and
a plurality of heat pipes formed in the dielectric layer, and disposed outside the device region;
wherein a predetermined one of the plurality of second interconnect layers further includes a first metal line that extends from a point in the device region to at least one of the plurality of heat pipes.

2. The semiconductor device according to claim 1, wherein:
the predetermined one of the plurality of second interconnect layers further includes a second metal line that is disposed outside the device region and that is connected to at least two of the plurality of heat pipes.

3. The semiconductor device according to claim 1, wherein:
the device region includes a hot spot; and
the point from which the first metal line extends is within the hot spot.

4. The semiconductor device according to claim 1, wherein:
the device region includes a hot spot; and
the point from which the first metal line extends is at a boundary of the hot spot.

5. The semiconductor device according to claim 1, wherein:
the device region includes a hot spot; and
the point from which the first metal line extends is outside of the hot spot and close to the hot spot.

6. The semiconductor device according to claim 1, wherein:
the first metal line has a minimum width that is no less than 10 nm.

7. The semiconductor device according to claim 1, wherein:
the predetermined one of the plurality of second interconnect layers has a via density that falls within a range of from 0.5% to 20%.

8. The semiconductor device according to claim 1, wherein:
a pair of the plurality of first interconnect layers that is adjacent to the predetermined one of the plurality of second interconnect layers has a minimum pitch that is no greater than 100 nm.

9. The semiconductor device according to claim 1, wherein:
a pair of the plurality of first interconnect layers that is adjacent to the predetermined one of the plurality of second interconnect layers has a thickness that falls within a range of from 100 Å to 1000 Å.

10. The semiconductor device according to claim 1, wherein:
the predetermined one of the plurality of second interconnect layers has a thickness that falls within a range of from 100 Å to 500 Å.

11. The semiconductor device according to claim 1, wherein:
each of the plurality of heat pipes has a radius that falls within a range of from 20 nm to 1000 nm.

12. A semiconductor device including a device region, and comprising:
an interconnect structure including
a plurality of first interconnect layers formed in a dielectric layer, and each including a plurality of metal lines disposed in the device region, and
a plurality of second interconnect layers formed in the dielectric layer, interleaving the plurality of the first interconnect layers, and each including a plurality of vias disposed in the device region; and
a plurality of heat pipes formed in the dielectric layer, and disposed outside the device region;
wherein a predetermined one of the plurality of second interconnect layers further includes a first metal line that is disposed outside the device region and that is connected to at least two of the plurality of heat pipes.

13. The semiconductor device according to claim 12, wherein:
the predetermined one of the plurality of second interconnect layers further includes a second metal line that extends from a point in the device region to the first metal line.

14. The semiconductor device according to claim 13, wherein:
the device region includes a hot spot; and
the point from which the second metal line extends is within the hot spot.

15. The semiconductor device according to claim 13, wherein:
the device region includes a hot spot; and
the point from which the second metal line extends is at a boundary of the hot spot.

16. The semiconductor device according to claim 13, wherein:
the device region includes a hot spot; and
the point from which the second metal line extends is outside of the hot spot and close to the hot spot.

17. A method for manufacturing a semiconductor device, comprising:
forming a first interconnect layer and a plurality of first heat pipe portions, where the first interconnect layer includes a plurality of metal lines that are disposed in a device region of the semiconductor device, and the plurality of first heat pipe portions are disposed outside the device region;
forming a second interconnect layer that includes a plurality of vias and a first metal line, where the plurality of vias are disposed in the device region, and the first metal line extends from a point in the device region to outside of the device region; and
forming a third interconnect layer and a plurality of second heat pipe portions, where the third first interconnect layer includes a plurality of metal lines that are disposed in the device region, and the plurality of second heat pipe portions are disposed outside the device region;
wherein the first metal line is connected to at least one of the plurality of first heat pipe portions and the plurality of second heat pipe portions.

18. The method according to claim 17, wherein:
the second interconnect layer further includes a second metal line that is disposed outside the device region and that is connected to at least two of the plurality of first heat pipe portions.

19. The method according to claim 17, wherein:
the second interconnect layer further includes a second metal line that is disposed outside the device region and that is connected to at least two of the plurality of second heat pipe portions.

20. The method according to claim 17, wherein:
the plurality of vias and the first metal line are made of copper, cobalt, tungsten, molybdenum, ruthenium, aluminum, niobium, copper aluminum, nickel aluminum, or combinations thereof.
